(19) United States
(12) Patent Application Publication
(10) Pub. No.: US 2024/0215165 A1
(43) Pub. Date: Jun. 27, 2024

(54) PRINTED CIRCUIT BOARD

(71) Applicant: SAMSUNG ELECTRO-MECHANICS CO., LTD., Suwon-si (KR)

(72) Inventors: Myong Keun Jung, Suwon-si (KR); Hyun Woo Kwon, Suwon-si (KR)

(73) Assignee: SAMSUNG ELECTRO-MECHANICS CO., LTD., Suwon-si (KR)

(21) Appl. No.: 18/200,224

(22) Filed: May 22, 2023

(30) Foreign Application Priority Data
Dec. 23, 2022 (KR) 10-2022-0182720

(51) Int. Cl. H05K 1/11; H05K 1/02; H05K 3/46

(52) U.S. Cl. CPC H05K 1/115; H05K 1/0298; H05K 3/4652; H05K 2201/09563

(57) ABSTRACT

A printed circuit board includes: a first board unit including a first insulating layer having a first via hole, a first wiring layer disposed on or in the first insulating layer, and a first via including a first metal layer substantially filling the first via hole; and a second board unit including a second insulating layer having a second via hole, a second wiring layer disposed on or in the second insulating layer, and a second via including a second metal layer substantially filling the second via hole. The second board unit is disposed on the first board unit, the second wiring layer has a higher wiring density than that of the first wiring layer, and the second metal layer has a plating structure different from that of the first metal layer.

### CROSS-REFERENCE TO RELATED APPLICATION(S)

This application claims benefit of priority to Korean Patent Application No. 10-2022-0182720 filed on Dec. 23, 2022 in the Korean Intellectual Property Office, the disclosure of which is incorporated herein by reference in its entirety.

### TECHNICAL FIELD

The present disclosure relates to a printed circuit board.

### BACKGROUND

Chiplet technology is emerging in accordance with a limitation in increasing a size of a semiconductor chip to cope with multifunctionality and the implementation of high performance thereof, and accordingly, a wiring of a package board has a gradually smaller line or space. Meanwhile, in a case of a via hole formed in a microcircuit layer, even though having a lower depth and a smaller hole size, the via hole may be formed using substantially the same plating method as a general circuit layer, and there is thus a limitation in lowering manufacturing costs thereof, and in improving reliability of the via as well.

### SUMMARY

An aspect of the present disclosure may provide a printed circuit board with a simplified process of forming a via in a microcircuit layer, reduced production lead time, improved time and yield, and lower costs.

Another aspect of the present disclosure may provide a printed circuit board having improved reliability of a via in a microcircuit layer.

The present disclosure may provide a printed circuit board which is a package board including a first board unit including a general circuit layer and a second board unit including a microcircuit layer. Filling plating of a via formed in the general circuit layer and that of a via formed in the microcircuit layer may be performed in a different manner.

According to an aspect of the present disclosure, a printed circuit board may include: a first board unit including a first insulating layer having a first via hole, a first wiring layer disposed on or in the first insulating layer, first via including a first metal layer substantially filling the first via hole; and a second board unit including a second insulating layer having a second via hole, a second wiring layer disposed on or in the second insulating layer, and a second via including a second metal layer substantially filling the second via hole. The second board unit may be disposed on the first board unit, the second wiring layer may have a higher wiring density than that of the first wiring layer, and the second metal layer may have a plating structure different from that of the first metal layer.

According to another aspect of the present disclosure, a printed circuit board may include: a first board unit including a first insulating layer including a first insulating resin and first inorganic filler particles, a first via hole passing through at least a portion of the first insulating layer, and a first via including electrolytic copper substantially filling the first via hole; and a second board unit including a second insulating layer including a second insulating resin and second inorganic filler particles, a second via hole passing through at least a portion of the second insulating layer, and a second via including chemical copper substantially filling the second via hole. The second board unit may be disposed on the first board unit, and based on a cross section of the printed circuit board, an average diameter of the second inorganic filler particles may be smaller than an average diameter of the first inorganic filler particles.

According to another aspect of the present disclosure, a printed circuit board may include: a first insulating layer having a first via hole; a first wiring layer disposed on or in the first insulating layer; a first via disposed in the first via hole to connect to the first wiring layer; a second insulating layer having a second via hole; a second wiring layer disposed on or in the second insulating layer; and a second via disposed in the second via hole to connect to the second wiring layer. The second insulating layer may be thinner than the first insulating layer, and the number of layers of the first via may be greater than that of the second via.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a printed circuit board according to an exemplary embodiment;

FIG. 4 is a cross-sectional view schematically illustrating an example of a region A1 of FIG. 3;

FIG. 5 is a cross-sectional view schematically illustrating an example of a region A2 of FIG. 3;

FIG. 6 is a cross-sectional view schematically illustrating another example of the region A2 of FIG. 3;

FIG. 7 is an image schematically illustrating plating structures of chemical copper and electrolytic copper; and

FIGS. 8 and 9 are images schematically illustrating cross-sectional structures of first and second insulating layers respectively included in first and second board units.

### DETAILED DESCRIPTION

Hereinafter, exemplary embodiments of the present disclosure will now be described in detail with reference to the accompanying drawings.

### Electronic Device

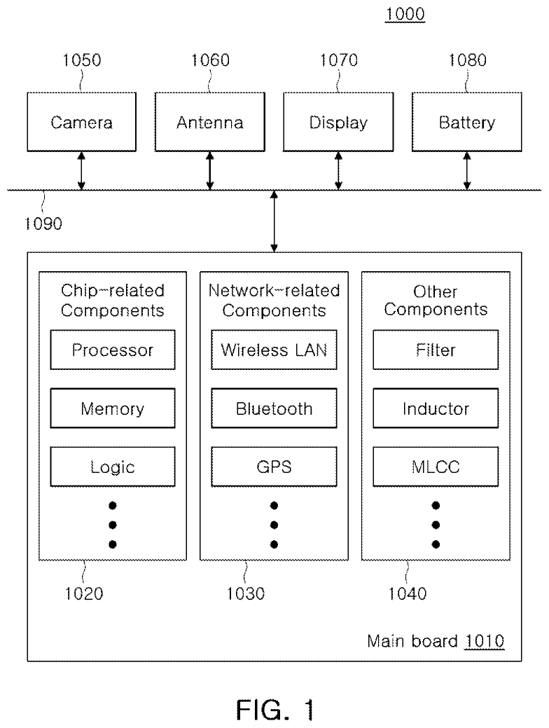

FIG. 1 is a block diagram schematically illustrating an example of an electronic device system.

Referring to FIG. 1, an electronic device 1000 may accommodate a main board 1010. The main board 1010 may include chip-related components 1020, network-related components 1030, other components 1040 and the like, which are physically or electrically connected thereto. These components may be connected to other electronic components described below to form various signal lines 1090.

The chip-related components 1020 may include a memory chip such as a volatile memory (for example, a dynamic random access memory (DRAM)), a non-volatile memory (for example, a read only memory (ROM)), or a flash memory; an application processor chip such as a central processor (for example, a central processing unit (CPU)), a graphics processor (for example, a graphics processing unit (GPU)), a digital signal processor, a cryptographic processor, a microprocessor, or a microcontroller; and a logic chip such as an analog-to-digital (ADC) converter or an application-specific integrated circuit (ASIC). However, the chip-related components 1020 are not limited thereto, and may also include other types of chip-related components. In addition, the chip-related components 1020 may be combined with each other. The chip-related component 1020 may be a package including the above-mentioned chip or electronic component.

The network-related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 1G, 2G, and 5G protocols, and any other wireless and wired protocols designated after the above-mentioned protocols. However, the network-related components 1030 are not limited thereto, and may also include any of various other wireless or wired standards or protocols. In addition, the network-related components 1030 may be combined with the chip-related components 1020.

The other components 1040 may include a high frequency inductor, a ferrite inductor, a power inductor, ferrite beads, low temperature co-firing ceramics (LTCC), an electromagnetic interference (EMI) filter, a multi-layer ceramic condenser (MLCC) and the like. However, the other components 1040 are not limited thereto, and may further include a passive device in the form of a chip component used for various other purposes in addition to these components. In addition, the other components 1040 may be combined with the chip-related components 1020 or the network-related components 1030.

The electronic device 1000 may include another electronic component that may be or may not be physically or electrically connected to the main board 1010, based on a type of the electronic device 1000. Another electronic component may be a camera module 1050, an antenna module 1060, a display 1070, a battery 1080, etc. However, another electronic component is not limited thereto, and may be an audio codec, a video codec, a power amplifier, a compass, an accelerometer, a gyroscope, a speaker, a mass storage device (e.g., a hard disk drive), a compact disk (CD), a digital versatile disk (DVD), etc. In addition, another electronic component may be another electronic component used for various purposes, based on the type of the electronic device 1000.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, an automotive or the like. However, the electronic device 1000 is not limited thereto, and may also be any other electronic device processing data.

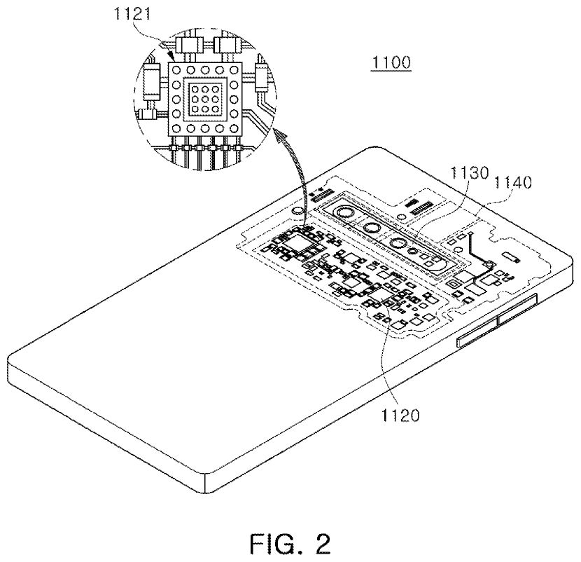

FIG. 2 is a perspective view schematically illustrating an example of an electronic device.

Referring to FIG. 2, the electronic device may be, for example, a smartphone 1100. The smartphone 1100 may accommodate a motherboard 1110, and various components 1120 may be physically or electrically connected to the motherboard 1110. In addition, the motherboard 1110 may accommodate other components that may or may not be physically or electrically connected thereto, such as the camera module 1130 or a speaker 1140. Some of the components 1120 may be the chip-related components, for example, a component package 1121, and are not limited thereto. The component package 1121 may be in the form of a printed circuit board on which electronic components including active components or passive components are surface mounted. Alternatively, the component package 1121 may be in the form of a printed circuit board in which the active components or the passive components are embedded. Meanwhile, the electronic device is not necessarily limited to the smartphone 1100, and may be another electronic device as described above.

### Printed Circuit Board

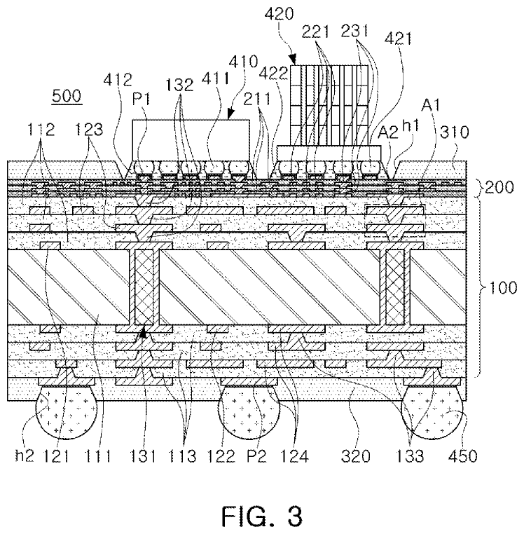

FIG. 3 is a cross-sectional view schematically illustrating a printed circuit board according to an exemplary embodiment.

Referring to FIG. 1, a printed circuit board 500 according to an exemplary embodiment may be a multilayer printed circuit board including a first board unit 100 and a second board unit 200. For example, the printed circuit board 500 according to an exemplary embodiment may be a package board including a rewiring layer which may electrically connect a plurality of semiconductor chips mounted on the board to each other. For example, the first board unit 100 may be a core-type board. For example, the first board unit 100 may include a build-up part including a general circuit layer formed on each of two sides of a core part. On the other hand, the second board unit 200 may be a coreless-type board. For example, the second board unit 200 may include a build-up part including a microcircuit layer. The first board unit 100 and the second board unit 200 may be directly stacked vertically to form the multilayer printed circuit board.

Meanwhile, a build-up wiring layer 221 included in the second board unit 200 may have a higher wiring density than those of core wiring layers 121 and 122 or build-up wiring layers 123 and 124, included in the first board unit 100. For example, the build-up wiring layer 221 of the second board unit 200 may include a higher-density wiring with a relatively fine pitch, and each of the core wiring layers 121 and 122 or build-up wiring layers 123 and 124 of the first board unit 100 may include a lower-density wiring. For example, the build-up wiring layer 221 of the second board unit 200 may have smaller wiring thickness, lines/space, pitch, or the like than those of the core wiring layers 121 and 122 or build-up wiring layers 123 and 124 of the first board unit 100. In addition, an insulation distance between the build-up wiring layers 221 disposed on different layers of the second board unit 200 may also be smaller than an insulation distance between the core wiring layers 121 and 122 or the build-up wiring layers 123 and 124, disposed on different layers of the first board unit 100. Meanwhile, the thickness, line, space, pitch, or the like may be measured using a scanning microscope or an optical microscope based on a polished or cut cross section of the printed circuit board. When these values are not constant, the value may be compared with an average value of values measured at five random points.

Meanwhile, the printed circuit board 500 according to an exemplary embodiment may further include: a plurality of first outer pads P1 disposed on the second board unit 200; a first resist layer 310 disposed on the second board unit 200 and having a first opening h1 exposing the plurality of first outer pads P1; a plurality of second outer pads P2 disposed under the first board unit 100; a second resist layer 320 disposed under the first board unit 100 and having a plurality of second openings h2 each exposing at least a portion of each of the plurality of second outer pads P2; a first semiconductor chip 410 disposed on the second board unit 200 and connected to some of the plurality of first outer pads P1 through a plurality of first connection members 411; a second semiconductor chip 420 disposed above the first board unit 100 and connected to another some of the plurality of first outer pads P1 through a plurality of second connection members 421; and/or a plurality of third connection members 450 disposed under the first board unit 100 and respectively connected to the plurality of second outer pads P2.

Hereinafter, the components of the printed circuit board 500 according to an exemplary embodiment are described in more detail with reference to the drawings.

The first board unit 100 may be a core-type multilayer board. For example, the first board unit 100 may include a core insulating layer 111, the first and second core wiring layers 121 and 122 respectively disposed on upper and lower surfaces of the core insulating layer 111, a through via layer 131 passing through the core insulating layer 111 and connecting the first and second core wiring layers 121 and 122 to each other, a plurality of first build-up insulating layers 112 disposed on the upper surface of the core insulating layer 111, the plurality of first build-up wiring layers 123 respectively disposed on or in the plurality of first build-up insulating layers 112, a plurality of first connection via layers 132 each passing through at least one of the plurality of first build-up insulating layers 112 and each connected to at least one of the plurality of first build-up wiring layers 123, a plurality of second build-up insulating layers 113 disposed on the lower surface of the core insulating layer 111, the plurality of second build-up wiring layers 124 respectively disposed on or in the plurality of second build-up insulating layers 113, and a plurality of second connection via layers 133 each passing through at least one of the plurality of second build-up insulating layers 113 and each connected to at least one of the plurality of second build-up wiring layers 124.

The core insulating layer 111 may include an insulating material. The insulating material may use a thermosetting resin such as an epoxy resin or a thermoplastic resin such as polyimide, a material in which this insulating resin is mixed with an inorganic filler such as silica, a resin impregnated into a core material such as a glass fiber (i.e., glass fiber, glass cloth or glass fabric) together with the inorganic filler, for example, copper clad laminate (CCL), or the like, and is not limited thereto. The core insulating layer 111 may be thicker than each of the first and second build-up insulating layers 112 and 113, and is not limited to this thickness.

Each of the first and second build-up insulating layers 112 and 113 may include an insulating material. The insulating material may use the thermosetting resin such as the epoxy resin or the thermoplastic resin such as the polyimide, the material in which this insulating resin is mixed with the inorganic filler such as silica, the resin impregnated into the core material such as the glass fiber (i.e., glass fiber, glass cloth or glass fabric) together with the inorganic filler, for example, Ajinomoto build-up film (ABF), prepreg, or resin coated copper (RCC), and is not limited thereto. The first and second build-up insulating layers 112 and 113 are not limited to a specific number of layers, may have the same number of layers, and are not limited thereto.

The first and second core wiring layers 121 and 122 may each include a metal material. The metal material may use copper (Cu), aluminum (Al), silver (Ag), tin (Sn), gold (Au), nickel (Ni), lead (Pb), titanium (Ti), or alloys thereof. The first and second core wiring layers 121 and 122 may each include an electroless plating layer (or chemical copper) and an electrolytic plating layer (or electrolytic copper). Meanwhile, the first and second core wiring layers 121 and 122 may each include a sputtering layer instead of the electroless plating layer, or include both the layers, if necessary. In addition, the first and second core wiring layers 121 and 122 may each further include a copper foil. The first and second core wiring layers 121 and 122 may respectively perform various functions based on designs thereof. For example, the first and second core wiring layers 121 and 122 may each include a ground pattern, a power pattern, a signal pattern, or the like. Here, the signal pattern may include various signals other than the ground pattern, the power pattern, and the like, for example, a data signal. Each of these patterns may include a line pattern, a plane pattern, or a pad pattern.

Each of the first and second build-up wiring layers 123 and 124 may include a metal material. The metal material may use copper (Cu), aluminum (Al), silver (Ag), tin (Sn), gold (Au), nickel (Ni), lead (Pb), titanium (Ti), or alloys thereof. The first and second build-up wiring layers 123 and 124 may each include an electroless plating layer (or chemical copper) and an electrolytic plating layer (or electrolytic copper), and are not limited thereto. The first and second build-up wiring layers 123 and 124 may each include the sputtering layer instead of the electroless plating layer, or include both the layers. In addition, the first and second build-up wiring layers 123 and 124 may each include the copper foil. The first and second build-up wiring layers 123 and 124 may respectively perform various functions based on designs thereof. For example, the first and second build-up wiring layers 123 and 124 may each include the ground pattern, the power pattern, the signal pattern, or the like. Here, the signal pattern may include various signals other than the ground pattern, the power pattern, and the like, for example, the data signal. Each of these patterns may include the line pattern, the plane pattern, or the pad pattern.

The through via layer 131 may include a through via. The through via may include a metal layer formed on a wall surface of a through hole and a plug filling the metal layer. The metal layer may include a metal material such as copper (Cu), aluminum (Al), silver (Ag), tin (Sn), gold (Au), nickel (Ni), lead (Pb), titanium (Ti), or alloys thereof. The plug may include ink including the insulating material. The metal layer may include an electroless plating layer (or chemical copper) and an electrolytic plating layer (or electrolytic copper), and is not limited thereto. The through via layer 131 may include the sputtering layer instead of the electroless plating layer, or include both the layers. The through via layer 131 may perform various functions based on a design thereof. For example, the through via layer 131 may include a ground via, a power via, a signal via, or the like. Here, the signal via may include a via for transferring various signals other than the ground via, the power via, and the like, for example, the data signal.

The first and second connection via layers 132 and 133 may include micro vias. The micro via may be a filled via filling a via hole or a conformal via that is disposed along a wall surface of the via hole. The micro vias may be disposed in a stacked type or a staggered type. Each of the first and second connection via layers 132 and 133 may include a metal material, and the metal material may include copper (Cu), aluminum (Al), silver (Ag), tin (Sn), gold (Au), nickel (Ni), lead (Pb), titanium (Ti), or alloys thereof. The first and second connection via layers 132 and 133 may each include an electroless plating layer (or chemical copper) and an electrolytic plating layer (or electrolytic copper), and are not limited thereto. The first and second connection via layers 132 and 133 may each include the sputtering layer instead of the electroless plating layer, or include both the layers. The first and second connection via layers 132 and 133 may respectively perform various functions based on designs thereof. For example, the first and second connection via layers 132 and 133 may each include a ground via, a power via, a signal via, or the like. Here, the signal via may include a via for transferring various signals other than the ground via, the power via, and the like, for example, the data signal.

The second board unit 200 may be a coreless-type multilayer build-up board including a microcircuit. For example, the second board unit 200 may include a plurality of third build-up insulating layers 211, the plurality of third build-up wiring layers 221 respectively disposed on or in the plurality of third build-up insulating layers 211, and a plurality of third connection via layers 231 each passing through at least one of the plurality of third build-up insulating layers 211 and each connected to at least one of the plurality of third build-up wiring layers 221.

The third build-up insulating layer 211 may include an insulating material. The insulating material may use the thermosetting resin such as the epoxy resin or the thermoplastic resin such as the polyimide, the material in which this insulating resin is mixed with the inorganic filler such as silica, the resin impregnated into the core material such as the glass fiber (i.e., glass fiber, glass cloth or glass fabric) together with the inorganic filler, for example, Ajinomoto build-up film (ABF), prepreg, resin coated copper (RCC), or the like, and is not limited thereto. If necessary, the third build-up insulating layer 211 may include a photosensitive insulating material, for example, a photoimageable dielectric (PID). The third build-up insulating layer 211 is not limited to a specific number of layers.

The third build-up wiring layer 221 may include a metal material. The metal material may use copper (Cu), aluminum (Al), silver (Ag), tin (Sn), gold (Au), nickel (Ni), lead (Pb), titanium (Ti), or alloys thereof. The third build-up wiring layer 221 may include only the electroless plating layer (or chemical copper), is not limited thereto, and may further include the electrolytic plating layer (or electrolytic copper). In addition, the third build-up wiring layer 221 may further include the sputtering layer in addition to the electroless plating layer. The third build-up wiring layer 221 may perform various functions based on a design thereof. For example, the third build-up wiring layer 221 may include the ground pattern, the power pattern, the signal pattern, or the like. Here, the signal pattern may include various signals other than the ground pattern, the power pattern, and the like, for example, the data signal. Each of these patterns may include the line pattern, the plane pattern, or the pad pattern.

The third connection via layer 231 may include a micro via. The micro via may be the filled via filling the via hole or the conformal via that is disposed along the wall surface of the via hole. The micro vias may be disposed in the stacked type or the staggered type. The third connection via layer 231 may include a metal material, and the metal material may include copper (Cu), aluminum (Al), silver (Ag), tin (Sn), gold (Au), nickel (Ni), lead (Pb), titanium (Ti), or alloys thereof. The third connection via layer 231 may include only the electroless plating layer (or chemical copper), is not limited thereto, and may further include the sputtering layer, if necessary. The third connection via layer 231 may perform various functions based on a design thereof. For example, the third connection via layer 231 may include a ground via, a power via, a signal via, or the like. Here, the signal via may include a via for transferring various signals other than the ground via, the power via, and the like, for example, the data signal.

The first and second resist layers 310 and 320 may each include the insulating material, and the insulating material may use a liquid-type or film-type solder resist. However, the first or second resist layer 310 or 320 is not limited thereto, and may use another type of material. The first resist layer 310 may include the first opening h1 exposing at least a portion of each of the plurality of first outer pads P1 disposed on an upper surface of the uppermost build-up wiring layer of the second board unit 200. For example, one first opening h1 may expose at least a portion of each of the plurality of first outer pads P1. A first surface treatment layer may be formed on each of the plurality of first outer pads P1 exposed through the first opening h1. Each of the first surface treatment layers may cover the upper surface and side surface of each of the first outer pads P1. The second resist layer 320 may include the plurality of second openings h2 each exposing at least a portion of each of the plurality of second outer pads P2 disposed on a lower surface of the lowermost build-up wiring layer of the first board unit 100. For example, the plurality of second openings h2 may each expose at least a portion of each of the plurality of second outer pads P2. A second surface treatment layer may be formed on each of the plurality of second outer pads P2 exposed through each second opening h2. Each of the second surface treatment layers may cover a lower surface of each of the second outer pads P2.

Each of the first and second semiconductor chips 410 and 420 may include an integrated circuit (IC) die in which hundreds to millions of elements or more are integrated into one chip. In this case, the IC may be, for example, a central processor (for example, a central processing unit (CPU)), a graphic processor (for example, a graphics processing unit (GPU)), a field programmable gate array (FPGA), a digital signal processor, a cryptographic processor, a microprocessor, a micro controller, an application processor (e.g., AP), an analog-to-digital converter, or a logic chip such as an application-specific IC (ASIC), and is not limited thereto. The semiconductor chip may be a memory chip such as a volatile memory for example, a dynamic random access memory (DRAM)), a non-volatile memory (for example, a read only memory (ROM)), or a flash memory, a high bandwidth memory (HBM), or another type such as a power management IC (PMIC). For example, the first semiconductor chip 410 may be the logic chip such as the CPU or the GPU, and the second semiconductor chip 420 may be the memory chip such as the HBM, and are not limited thereto.

The first and second semiconductor chips 410 and 420 may each be formed on the basis of an active wafer. In this case, a base material of each of bodies of the first and second semiconductor chips 410 and 420 may be silicon (Si), germanium (Ge), gallium arsenide (GaAs), or the like. Various circuits may be formed on the body. A connection pad may be formed on each body, and the connection pad may include a conductive material such as aluminum (Al) or copper (Cu). The first and second semiconductor chips 410 and 420 may be bare dies, and in this case, a metal bump may be disposed on the connection pad, if necessary. The first and second semiconductor chips 410 and 420 may also be packaged dies. In this case, a rewiring layer may be additionally formed on the connection pad, and the metal bump may be disposed on the rewiring layer, if necessary.

The first and second semiconductor chips 410 and 420 may each be mounted on the first resist layer 310 through the plurality of first and second connection members 411 and 421. For example, the first and second semiconductor chips 410 and 420 may be independently electrically connected to the plurality of first outer pads P1 through the plurality of first and second connection members 411 and 421, respectively. In addition, the first and second semiconductor chips 410 and 420 may respectively be fixed through first and second underfills 412 and 422. Each of the plurality of first and second connection members 411 and 421 may be formed of a low melting point metal, for example, a solder such as tin (Sn)-aluminum (Al)-copper (Cu), or the like. However, this is only an example, and each of the first and second connection members 411 and 421 is not limited to a specific material. The first and second underfills 412 and 422 may each include an adhesive component such as epoxy, and are not limited thereto.

The plurality of third connection members 450 may be components for connecting the printed circuit board 500 to the main board or another board of the electronic device. The plurality of third connection members 450 may be independently electrically connected to the plurality of second outer pads P2, respectively. If necessary, each of the plurality of third connection members 450 may also be disposed through an under bump metal including a known metal material. Each of the plurality of third connection members 450 may be made of the conductive material, for example, the solder, which is only an example, and is not limited thereto a specific material. Each of the plurality of third connection members 450 may be a land, a ball, or a pin. Each of the plurality of third connection members 450 may be formed as a multilayer or a single layer. Each of the plurality of third connection members 450 may include a copper pillar and the solder when formed as the multilayer, or include a tin-silver solder or copper when formed as the single layer, and is not limited thereto.

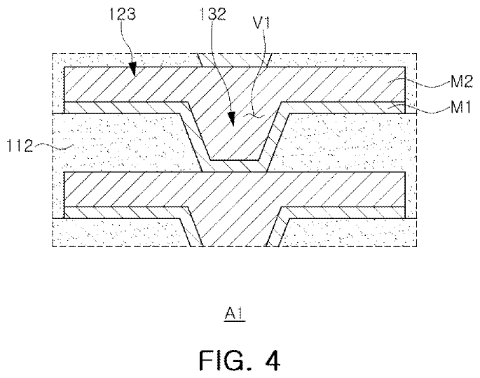

FIG. 4 is a cross-sectional view schematically illustrating an example of a region A1 of FIG. 3.

Referring to FIG. 4, in the first board unit 100, at least one of the plurality of first build-up insulating layers 112 may have a first via hole V1, at least one of the plurality of first build-up wiring layers 123 may include a first metal layer M1 and a second metal layer M2, and at least one of the plurality of first connection via layers 132 may include the first metal layer M1 and the second metal layer M2. The first metal layer M1 may be disposed on an upper surface of at least one of the plurality of first build-up insulating layers 112 and extended to a wall surface of the first via hole V1 formed in at least one of the plurality of first build-up insulating layers 112. The second metal layer M2 may be disposed on the first metal layer M1, and may substantially fill the first via hole V1 while being spaced apart from the wall surface of the first via hole V1 due to the disposition of the first metal layer M1. Substantially filling may include, for example, filling with fill plating, and may include not only a case of completely filling, but also a case where there is a minute space due to a void or the like.

Meanwhile, the first metal layer M1 may include an electroless plating layer, for example, chemical copper. In addition, the second layer M2 may include an electrolytic plating layer, for example, electrolytic copper. For example, the first via hole V1 may be fill-plated with the electrolytic plating layer of the second metal layer M2, and the electroless plating layer of the first metal layer M1 may be a seed metal layer for electrolytic plating. Therefore, in the wiring layer, the first metal layer M1 may be thinner than the second metal layer M2. The thickness may be measured using the scanning microscope or the optical microscope based on the polished or cut cross section of the printed circuit board, and when the thickness is not constant, its value may be compared with the average value of the values measured at five random points. As described above, in the case of the first via hole V1 having significant average width and depth based on the cross section, the fill plating may be performed using the electrolytic plating to reduce process time.

Meanwhile, the above-described first via hole V1 and first and second metal layers M1 and M2 may be substantially equally applied to at least one of the plurality of second build-up insulating layers 113 of the first board unit 100, at least one of the second build-up wiring layers 124, and at least one of the second connection via layer 133, and the description thus omits redundant descriptions thereof.

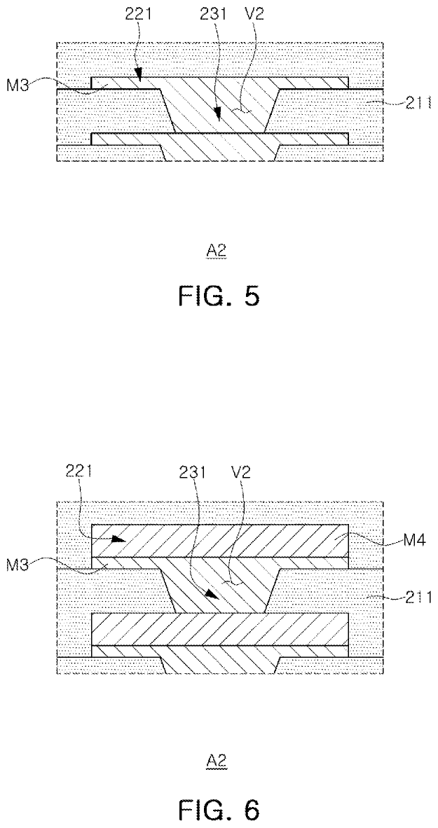

FIG. 5 is a cross-sectional view schematically illustrating an example of a region A2 of FIG. 3.

Referring to FIG. 5, in the second board unit 200, at least one of the plurality of first build-up insulating layers 211 may have a second via hole V2, at least one of the plurality of third build-up wiring layers 221 may include a third metal layer M3, and at least one of the plurality of third connection via layers 231 may also include the third metal layer M3. At least one of the plurality of third build-up wiring layers 221 and at least one of the plurality of third connection via layers 231 may each include only the third metal layer M3. For example, each of the above layers may not include another metal layer other than the third metal layer M3. For example, the third metal layer M3 may be disposed on an upper surface of at least one of the plurality of third build-up insulating layers 211, may be disposed on and in direct contact with a wall surface of the second via hole V2 formed in at least one of the plurality of third build-up insulating layers 211, and may substantially fill the second via hole V2. Substantially filling may include, for example, filling with the fill plating, and may include not only the case of completely filling, but also the case where there is a minute space due to a void or the like.

Meanwhile, the third metal layer M3 may include an electroless plating layer, for example, chemical copper. For example, the second via hole V2 may be fill-plated with the electrolytic plating layer of the third metal layer M3. In this case, it is possible to lower a manufacturing cost, and improve reliability of a via formed in the second via hole V2. In more detail, the second board unit 200 may include the rewiring layer, that is, the microcircuit layer for the electrical connection between the first and second semiconductor chips 410 and 420 as described above, and the second via hole V2 may thus be a finer hole than the first via hole V1. For example, the second via hole V2 may have average width and depth smaller than those of the first via hole V1 based on the cross section. For example, the second via hole V2 may have an average width of 10 μm or less and a depth of 7 μm or less based on the cross section. The width and the depth may each be measured using the scanning microscope or the optical microscope based on the polished or cut cross section of the printed circuit board, and its average value may be compared with the average value of the values measured at five random points. As such, the fine second via hole V2 may be sufficiently filled only with the electroless plating, and in this case, the electrolytic plating may be omitted, which may lead to a simplified process, reduced production lead time, improved time and yield, a lower cost, or the like. For example, compared to filling the via hole by dividing chemical copper and electrolytic copper, it is possible to reduce the production lead time through the simplified process, improve the time and yield by configuring development/exfoliation/etching after the exposure in-line, and lower the investment cost by reducing investment in electrolytic copper equipment. In addition, it is possible to improve the reliability of the via formed in the second via hole V2 because the inside of the second via hole V2 is integrated with an electroless plating layer, for example, chemical copper, thus unifying a plating structure. In addition, a wiring layer connected to the via formed in the second via hole V2, for example, at least one of the plurality of third build-up wiring layers 221, may also be formed only by the electroless plating. Therefore, it is possible to form a wiring included in each of the above layers to be finer and thinner. Similarly, it is possible to have an effect such as the simplified process, the reduced production lead time, the improved time and yield, and the lower cost.

FIG. 6 is a cross-sectional view schematically illustrating another example of the region A2 of FIG. 3.

Referring to FIG. 6, in another example, unlike an example described above, at least one of the plurality of third build-up wiring layers 221 may further include a fourth metal layer M4. The fourth metal layer M4 may be disposed on the third metal layer M3. The fourth metal layer M4 may include an electrolytic plating layer, for example, electrolytic copper. The electroless plating layer of the third metal layer M3 may be a seed metal layer for the electrolytic plating. Therefore, in the wiring layer, the third metal layer M3 may be thinner than the fourth metal layer M4. The thickness may be measured using the scanning microscope or the optical microscope based on the polished or cut cross section of the printed circuit board, and when the thickness is not constant, its value may be compared with the average value of the values measured at five random points. In this way, when a wiring having a sufficient thickness is required, at least one of the plurality of third build-up wiring layers 221 may be formed as a multi-layered metal layer. Other contents are substantially the same as those in an example described above, and the description thus omits redundant descriptions thereof.

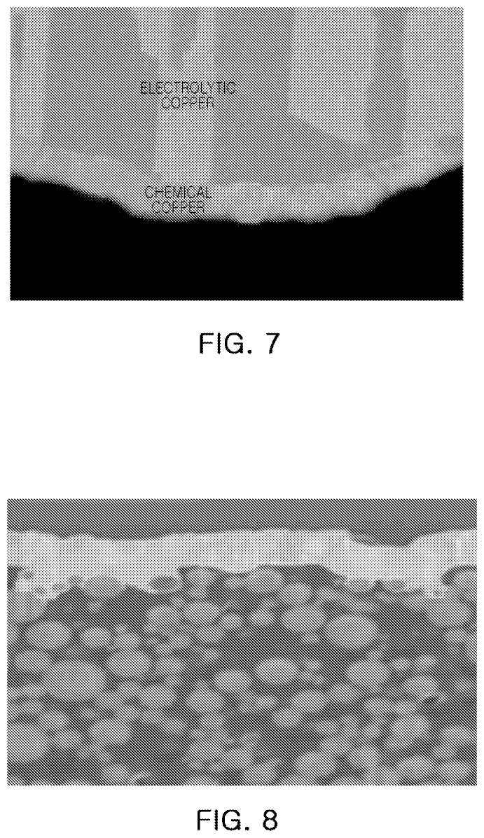

FIG. 7 is an image schematically illustrating the plating structures of chemical copper and electrolytic copper.

Referring to FIG. 7, chemical copper and electrolytic copper may have different plating structures. Thus, chemical copper and electrolytic copper may be distinguished from each other. For example, an average size of grains of a metal included in chemical copper may be smaller than an average size of grains of a metal included in electrolytic copper based on the cross section of the board. The size of the grain may be determined by comparing the area or diameter on the cross section, which may be measured using the scanning microscope or the optical microscope based on the polished or cut cross section of the printed circuit board. Its average value may be compared with the average value of the values measured at five random points. In addition, chemical copper may further include nickel (Ni) in addition to copper (Cu), electrolytic copper may include copper (Cu) without nickel (Ni), and these chemical copper and electrolytic copper are not limited thereto. The characteristics of these chemical copper and electrolytic copper may be substantially equally applied to the first to fourth metal layers M1, M2, M3, and M4, described above.

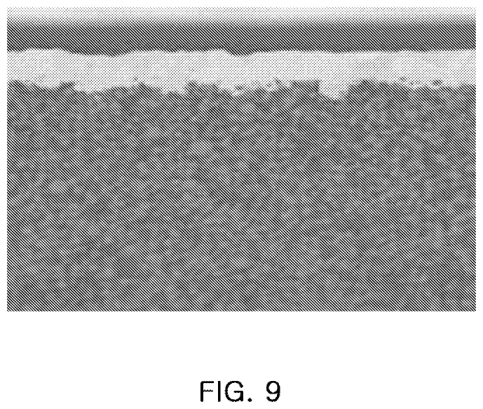

FIGS. 8 and 9 are images schematically illustrating cross-sectional structures of the first and second insulating layers respectively included in the first and second board units.

Referring to FIGS. 8 and 9, a first insulating resin and a first inorganic filler may be included in the first insulating layer included in the above-described first board unit 100, for example, at least one of the plurality of first and second build-up insulating layers 112 and 113 described above. In addition, a second insulating resin and a second inorganic filler may be included in the second insulating layer included in the above-described second board unit 200, for example, at least one of the plurality of third build-up insulating layers 211 described above. Here, in the cross section, an average diameter of the second inorganic filler particles included in the second insulating layer may be smaller than an average diameter of the first inorganic filler particles included in the first insulating layer. For example, the first inorganic filler particles may have an average diameter of 0.5 μm or more, the second inorganic filler particles may have an average diameter of 0.1 μm or less, and the filler particles are not limited thereto. The diameter may be measured using the scanning microscope or the optical microscope based on the polished or cut cross section of the printed circuit board, and its average value may be compared with the average value of the values measured at five random points. That is, the second insulating layer in which the smaller via hole is formed may include the inorganic filler having a smaller size than that of the first insulating layer in which the larger via hole is formed.

As set forth above, the present disclosure may provide the printed circuit board with the simplified process of forming the via in the microcircuit layer, the reduced production lead time, the improved time and yield, and the lower cost.

The present disclosure may also provide the printed circuit board with the improved reliability of the via in the microcircuit layer.

In the present disclosure, the cross-sectional shape may be a cross-sectional shape of an object when the object is vertically cut or its cross-sectional shape when the object is viewed from a side. In addition, the planar shape may be a shape of an object when the object is horizontally cut, or its planar shape when the object is viewed from top or bottom.

In the present disclosure, a lower side, a lower portion, a lower surface, and the like, are used to refer to a direction toward a surface on which the semiconductor package including an organic interposer is mounted based on cross sections of the drawings, for convenience, while an upper side, an upper portion, an upper surface, and the like, are used to refer to an opposite direction to the direction. However, these directions are defined for convenience of explanation, and the scope of the claims is not particularly limited by the directions defined as described above.

In the present disclosure, a meaning of the expression, “substantially,” may be determined by including a process error, a positional deviation, an error in measurement, and the like that occur in the process. In addition, connection between two components conceptually includes their indirect connection through a third component as well as their direct connection. In addition, it may be understood that when an element is referred to with terms such as “first” and “second,” the element is not limited thereby. These terms are used only to distinguish the element from another element, and may not limit the sequence or importance of the elements. In some cases, a first element may be referred to as a second element without departing from the scope of the claims set forth herein. Similarly, a second element may also be referred to as a first element.

The term “an exemplary embodiment” used herein does not refer to the same exemplary embodiment, and is provided to emphasize each particular feature different from that of another exemplary embodiment. However, the exemplary embodiments provided may herein be implemented in combination with features of another exemplary embodiment. For example, a description of an element in a specific exemplary embodiment may be understood as its description in another exemplary embodiment even though the element is not described in another exemplary embodiment, unless an opposite or contradictory description is provided therein.

The terms used herein are used only to describe an exemplary embodiment rather than limiting the present disclosure. Here, a term of a singular number includes its plural number unless explicitly interpreted otherwise in context.

While the exemplary embodiments have been shown and described above, it will be apparent to those skilled in the art that modifications and variations could be made without departing from the scope of the present disclosure as defined by the appended claims.

What is claimed is:

1. A printed circuit board, comprising:
a first board unit including a first insulating layer having a first via hole, a first wiring layer disposed on or in the first insulating layer, and a first via including a first metal layer substantially filling the first via hole; and
a second board unit including a second insulating layer having a second via hole, a second wiring layer disposed on or in the second insulating layer, and a second via including a second metal layer substantially filling the second via hole,
wherein the second board unit is disposed on the first board unit,
the second wiring layer has a higher wiring density than that of the first wiring layer, and
the second metal layer has a plating structure different from that of the first metal layer.

2. The printed circuit board of claim 1, wherein based on a cross section of the printed circuit board, an average size of grains of a metal included in the second metal layer is smaller than an average size of grains of a metal included in the first metal layer.

3. The printed circuit board of claim 1, wherein the first metal layer includes an electrolytic plating layer, and
the second metal layer includes an electroless plating layer.

4. The printed circuit board of claim 1, wherein the first metal layer is spaced apart from a wall surface of the first via hole, and
the second metal layer is in direct contact with a wall surface of the second via hole.

5. The printed circuit board of claim 4, wherein the first via further includes a third metal layer disposed on the wall surface of the second via hole and having a plating structure different from that of the first metal layer, and
the first metal layer is disposed on the third metal layer.

6. The printed circuit board of claim 5, wherein the first metal layer includes an electrolytic plating layer, and
the second and third metal layers each include an electroless plating layer.

7. The printed circuit board of claim 1, wherein based on a cross section of the printed circuit board, an average width of the second via hole is smaller than an average width of the first via hole, and a depth of the second via hole is smaller than a depth of the first via hole.

8. The printed circuit board of claim 1, wherein the first and second metal layers each include copper (Cu),
the first metal layer does not include nickel (Ni), and
the second metal layer further includes nickel (Ni).

9. The printed circuit board of claim 1, wherein the first and second insulating layers each include inorganic filler particles, and
based on a cross section of the printed circuit board, an average diameter of the inorganic filler particles included in the second insulating layer is smaller than an average diameter of the inorganic filler particles included in the first insulating layer.

10. The printed circuit board of claim 1, wherein the first wiring layer includes the first metal layer and a third metal layer disposed under the first metal layer and thinner than the first metal layer, and
the second wiring layer includes the second metal layer.

11. The printed circuit board of claim 10, wherein the second wiring layer does not include a metal layer other than the second metal layer,
the first metal layer includes an electrolytic plating layer, and
the second and third metal layers each include an electroless plating layer.

12. The printed circuit board of claim 10, wherein the second wiring layer further includes a fourth metal layer disposed on the second metal layer and thicker than the second metal layer,
the first and fourth metal layers each include an electrolytic plating layer, and
the second and third metal layers each include an electroless plating layer.

13. The printed circuit board of claim 1, wherein the first board unit includes a core insulating layer, first and second core wiring layers respectively disposed on upper and lower surfaces of the core insulating layer, a through via layer passing through the core insulating layer and connecting the first and second core wiring layers to each other, a plurality of first build-up insulating layers disposed on the upper surface of the core insulating layer, a plurality of first build-up wiring layers respectively disposed on or in the plurality of first build-up insulating layers, a plurality of first connection via layers each passing through at least one of the plurality of first build-up insulating layers and each connected to at least one of the plurality of first build-up wiring layers, a plurality of second build-up insulating layers disposed on the lower surface of the core insulating layer, a plurality of second build-up wiring layers respectively disposed on or in the plurality of second build-up insulating layers, and a plurality of second connection via layers each passing through at least one of the plurality of second build-up insulating layers and each connected to at least one of the plurality of second build-up wiring layers;
the first insulating layer is included in at least one of the plurality of first build-up insulating layers and the plurality of second build-up insulating layers;
the first wiring layer is included in at least one of the plurality of first build-up wiring layers and the plurality of second build-up wiring layers; and
the first via is included in at least one of the plurality of first connection via layers and the plurality of second connection via layers.

14. The printed circuit board of claim 13, wherein the second board unit includes a plurality of third build-up insulating layers, a plurality of third build-up wiring layers respectively disposed on or in the plurality of third build-up insulating layers, and a plurality of third connection via layers each passing through at least one of the plurality of third build-up insulating layers and each connected to at least one of the plurality of third build-up wiring layers;
the plurality of third build-up insulating layers include the second insulating layer;
the plurality of third build-up wiring layers include the second wiring layer; and
the plurality of third connection via layers include the second via.

15. The printed circuit board of claim 14, further comprising:
a plurality of first outer pads disposed on the second board unit;
a first resist layer disposed on the second board unit and having a first opening exposing the plurality of first outer pads;
a plurality of second outer pads disposed under the first board unit;
a second resist layer disposed under the first board unit and having a plurality of second openings each exposing at least a portion of each of the plurality of second outer pads;
a first semiconductor chip disposed on the second board unit and connected to some of the plurality of first outer pads through a plurality of first connection members;
a second semiconductor chip disposed on the second board unit and connected to another some of the plurality of first outer pads through a plurality of second connection members; and
a plurality of third connection members disposed under the first board unit and respectively connected to the plurality of second outer pads.

16. A printed circuit board, comprising:
a first board unit including a first insulating layer including a first insulating resin and first inorganic filler particles, a first via hole passing through at least a portion of the first insulating layer, and a first via including electrolytic copper substantially filling the first via hole; and
a second board unit including a second insulating layer including a second insulating resin and second inorganic filler particles, a second via hole passing through at least a portion of the second insulating layer, and a second via including chemical copper substantially filling the second via hole,
wherein the second board unit is disposed on the first board unit, and
based on a cross section of the printed circuit board, an average diameter of the second inorganic filler particles is smaller than an average diameter of the first inorganic filler particles.

17. The printed circuit board of claim 16, wherein based on the cross section, the inorganic filler particles included in the first insulating layer have the average diameter of 0.5 μm or more, and
the inorganic filler particles included in the second insulating layer have the average diameter of 0.1 μm or less.

18. A printed circuit board, comprising:
a first insulating layer having a first via hole;
a first wiring layer disposed on or in the first insulating layer;
a first via disposed in the first via hole to connect to the first wiring layer;
a second insulating layer having a second via hole;
a second wiring layer disposed on or in the second insulating layer; and
a second via disposed in the second via hole to connect to the second wiring layer,
wherein the second insulating layer is thinner than the first insulating layer, and
the number of layers of the first via is greater than that of the second via.

19. The printed circuit board of claim 18, wherein based on a cross section of the printed circuit board, an average width of the second via hole is smaller than an average width of the first via hole.

20. The printed circuit board of claim 18, wherein the first and second insulating layers each include inorganic filler particles, and
based on a cross section of the printed circuit board, an average diameter of the inorganic filler particles included in the second insulating layer is smaller than an average diameter of the inorganic filler particles included in the first insulating layer.

21. The printed circuit board of claim 18, further comprising:
a core insulating layer thicker than the first insulating layer and the second insulating layer; and
first and second core wiring layers respectively disposed on upper and lower surfaces of the core insulating layer,
wherein the first insulating layer is disposed between the core insulating layer and the second insulating layer.

22. The printed circuit board of claim 18, further comprising:
an outer pad disposed on the second insulating layer and connected to the second via;
a resist layer disposed on the second insulating layer and having an opening exposing the outer pad; and
a semiconductor chip disposed on the second insulating layer and connected to the outer pad through a connection member.

23. The printed circuit board of claim 18, wherein the first via and the second via are tapered in a same direction.
